(19) United States
(12) Patent Application Publication
(10) Pub. No.: US 2016/0239143 A1
(43) Pub. Date: Aug. 18, 2016

(54) DISPLAY DEVICE AND METHOD OF MANUFACTURING THE DISPLAY DEVICE

(71) Applicant: Samsung Display Co., Ltd., Yongin-City (KR)

(72) Inventor: Sunghoon Song, Yongin-City (KR)

(21) Appl. No.: 14/815,815

(22) Filed: Jul. 31, 2015

(30) Foreign Application Priority Data
Feb. 17, 2015 (KR) 10-2015-0024021

(51) Int. Cl. G06F 3/041; H01L 51/56; H01L 27/32; H01L 51/52; G06F 3/044; G09G 3/32

(52) U.S. Cl. CPC G06F 3/0416; G06F 3/0412; G06F 3/044; G09G 3/3208; H01L 27/323; H01L 27/3276; H01L 51/5253; H01L 51/56; G06F 2203/04112; H01L 2227/323

(57) ABSTRACT

A display device and a method of manufacturing the display device are disclosed. In one aspect, the display device includes a substrate having first and second surfaces opposing each other. A display layer is formed over the first surface of the substrate and includes a display element configured to generate an image. A touch pattern is formed over the second surface of the substrate, and the touch pattern is conductive and configured to recognize a touch thereon.

### INCORPORATION BY REFERENCE TO ANY PRIORITY APPLICATIONS

This application claims the benefit of Korean Patent Application No. 10-2015-0024021, filed on Feb. 17, 2015, in the Korean Intellectual Property Office, the disclosure of which is incorporated herein in its entirety by reference.

### BACKGROUND

1. Field

The described technology generally relates to a display device and a method of manufacturing the display device.

2. Description of the Related Technology

Recently, various types of display devices that have thin profiles and are lightweight are being used. Legacy display devices are being replaced with portable thin flat panel display devices. Also, a panel having touch functionality can be included in display devices.

### SUMMARY OF CERTAIN INVENTIVE ASPECTS

One inventive aspect relates to a display device having a panel with touch functionality and a method of manufacturing the display device.

Another aspect is a display device that includes a substrate; a display unit formed on a surface of the substrate and including a display device configured to realize an image; and a touch pattern formed on other surface of the substrate opposite the surface of the substrate on which the display unit is formed, wherein the touch pattern has conductivity and is configured to recognize a user's touch.

The display device can further include a touch mutual electrode formed on a surface of the display unit or in the display unit so as to face the touch pattern.

The touch pattern can include a plurality of conductive patterns that extend in a first direction, and the touch mutual electrode can include a plurality of conductive patterns that extend in a second direction crossing the first direction.

The touch pattern can include a transmissive conductive material.

The display unit can include at least one thin-film transistor (TFT) electrically connected to the display device, and the TFT can include an active layer, a gate electrode, a source electrode, and a drain electrode.

The display device can further include a touch mutual electrode formed of same material as the gate electrode and formed to face the touch pattern.

The display device can further include a scan line configured to apply a scan signal to the display device of the display unit and electrically connected to the gate electrode, and the scan line can be formed to face the touch pattern so that the display device can detect a change in a capacitance between the scan line and the touch pattern to recognize the user's touch.

The scan line can include one or more conductive lines that extend in a first direction, and the touch pattern can include a plurality of conductive patterns that extend in a second direction crossing the first direction.

The display device can further include a touch mutual electrode that is formed of a same material as the source electrode or the drain electrode and is formed to face the touch pattern.

The display device can further include a touch mutual electrode formed between the active layer and the gate electrode and facing the touch pattern.

The touch pattern can include a light-shielding material.

The touch pattern can have a plurality of openings.

The display device can further include a protective layer that covers the touch pattern.

The substrate can include a light-transmitting material.

The display device can further include an encapsulating unit that covers the display unit.

The display device can include an organic light-emitting device that includes a first electrode, a second electrode, and an intermediate layer, and the intermediate layer can be formed between the first electrode and the second electrode and at least can include an organic emission layer.

Another aspect is a method of manufacturing a display device that includes forming, on a surface of a substrate, a display unit that includes a display device configured to realize an image; and forming a touch pattern on other surface of the substrate opposite the surface of the substrate on which the display unit is formed, wherein the touch pattern has conductivity and is configured to recognizes a user's touch.

After the operation of forming the display unit, the method can further include an operation of forming an encapsulating unit that covers the display unit, and the operation of forming the touch pattern can be performed after the operation of forming the encapsulating unit.

The method can further include an operation of flipping over the substrate, and the operation of forming the touch pattern can be performed after the operation of forming the encapsulating unit and the operation of flipping over the substrate are performed after the forming of the encapsulating unit.

Another aspect is a display device comprising: a substrate having first and second surfaces opposing each other; a display layer formed over the first surface of the substrate and comprising a display element configured to generate an image; and a touch pattern formed over the second surface of the substrate, wherein the touch pattern is conductive and configured to recognize a touch thereon.

The above display device further comprises a touch mutual electrode formed over the display layer or in the display layer so as to face the touch pattern.

In the above display device, the touch pattern comprises a plurality of first conductive patterns extending in a first direction, wherein the touch mutual electrode comprises a plurality of second conductive patterns extending in a second direction crossing the first direction.

In the above display device, the touch pattern is formed of a transmissive conductive material.

In the above display device, the display layer comprises at least one thin-film transistor (TFT) electrically connected to the display element, wherein the at least one TFT comprises an active layer, a gate electrode, a source electrode, and a drain electrode.

The above display device further comprises a touch mutual electrode formed of the same material as the gate electrode and facing the touch pattern.

The above display device further comprises a scan line configured to apply a scan signal to the display element and electrically connected to the gate electrode, wherein the scan line faces the touch pattern, and wherein the touch pattern is further configured to detect a change in a capacitance between the scan line and the touch pattern so as to recognize the touch.

In the above display device, the scan line comprises one or more conductive lines extending in a first direction, wherein the touch pattern comprises a plurality of conductive patterns extending in a second direction crossing the first direction.

The above display device further comprises a touch mutual electrode formed of the same material as the source electrode or the drain electrode, wherein the touch mutual electrode faces the touch pattern.

The above display device further comprises a touch mutual electrode formed between the active layer and the gate electrode and facing the touch pattern.

In the above display device, the touch pattern is formed of a light-shielding material.

In the above display device, the touch pattern has a plurality of openings.

In the above display device, the openings are configured to decrease light-shielding in the touch pattern.

The above display device further comprises a protective layer at least partially covering the touch pattern.

In the above display device, the substrate is formed of a light-transmitting material.

The above display device further comprises an encapsulating layer covering the display layer.

In the above display device, the display element comprises an organic light-emitting diode (OLED) including a first electrode, a second electrode, and an intermediate layer, wherein the intermediate layer is formed between the first and second electrodes and comprises an organic emission layer.

Another aspect is a method of manufacturing a display device, the method comprising: forming a display layer over a first surface of a substrate, wherein the display layer comprises a display element configured to generate an image; and forming a touch pattern over a second surface of the substrate opposing the first surface, wherein the touch pattern is conductive and configured to recognize a touch thereon.

The above method further comprises forming an encapsulating layer covering the display layer, wherein the touch pattern formed after the encapsulating layer.

The above method further comprises flipping over the substrate, wherein the touch pattern is formed after the encapsulating layer, and wherein the substrate is flipped over after the encapsulating layer is formed.

### BRIEF DESCRIPTION OF THE DRAWINGS

FIG. 1 is a cross-sectional view that illustrates a display device according to an exemplary embodiment.

FIG. 2 illustrates an enlarged view of a portion K of the display device shown in FIG. 1.

FIG. 3 is a cross-sectional view that illustrates a modified embodiment of the display device shown in FIG. 1.

FIG. 4 is a cross-sectional view that illustrates a display device according to another exemplary embodiment.

FIG. 5 illustrates an enlarged view of a portion K of the display device shown in FIG. 4.

FIG. 6 show a circuit diagram that illustrates a touch pattern of the display device shown in FIG. 4.

FIG. 7 is a cross-sectional view that illustrates a display device according to another exemplary embodiment.

FIG. 8 is a magnified view that illustrates a portion K of the display device shown in FIG. 7.

FIG. 9 shows a circuit diagram that illustrates a touch pattern of the display device shown in FIG. 7.

FIG. 10 is a cross-sectional view that illustrates a display device according to another exemplary embodiment.

FIG. 11 illustrates an enlarged view of a portion K of the display device shown in FIG. 10.

FIG. 12 is a plan view of the portion K of FIG. 10 seen in direction A of FIG. 11.

FIGS. 13 and 14 are diagrams illustrating a method of manufacturing a display device, according to an exemplary embodiment.

### DETAILED DESCRIPTION OF CERTAIN INVENTIVE EMBODIMENTS

A display device that has the touch functionality includes a plurality of conductive patterns. In order to improve the accuracy of this functionality, it is important to improve manufacturing characteristics of the conductive patterns.

As the described technology allows for various changes and numerous embodiments, particular embodiments will be illustrated in the drawings and described in detail in the written description. Effects and features of the described technology and methods of accomplishing the same can be understood more readily by reference to the following detailed description of exemplary embodiments and the accompanying drawings. The described technology can, however, be embodied in many different forms and should not be construed as being limited to the embodiments set forth herein.

Hereinafter, one or more exemplary embodiments will be described below in more detail with reference to the accompanying drawings. Those components that are the same or are in correspondence are rendered the same reference numeral regardless of the figure number, and redundant explanations are omitted.

Hereinafter, in one or more exemplary embodiments, while such terms as “first,” “second,” etc., can be used, but such components must not be limited to the above terms, and the above terms are used only to distinguish one component from another.

Hereinafter, in one or more exemplary embodiments, a singular form can include plural forms, unless there is a particular description contrary thereto.

Hereinafter, in one or more exemplary embodiments, terms such as “comprise” or “comprising” are used to specify existence of a recited feature or component, not excluding the existence of one or more other recited features or one or more other components.

Hereinafter, in one or more exemplary embodiments, it will also be understood that when an element such as layer, region, area, or component is referred to as being “on” another element, it can be directly on the other element, or intervening elements such as layer, region, area, or component can also be interposed therebetween.

In the drawings, for convenience of description, the sizes of layers and regions are exaggerated for clarity. For example, a size and thickness of each element can be random for convenience of description, thus, one or more exemplary embodiments are not limited thereto.

Hereinafter, in one or more exemplary embodiments, X-axis, Y-axis, and Z-axis are not be limited to three axes on a rectangular coordinate system but can be interpreted as a broad meaning including the three axes. For example, the X-axis, Y-axis, and Z-axis can be perpendicular to each other or can indicate different directions that are not perpendicular to each other.

In one or more exemplary embodiments, an order of processes can be different from that is described. For example, two processes that are sequentially described can be substantially simultaneously or concurrently performed, or can be performed in an opposite order to the described order.

Expressions such as “at least one of,” when preceding a list of elements, modify the entire list of elements and do not modify the individual elements of the list. In this disclosure, the term “substantially” includes the meanings of completely, almost completely or to any significant degree under some applications and in accordance with those skilled in the art. The term “connected” can include an electrical connection.

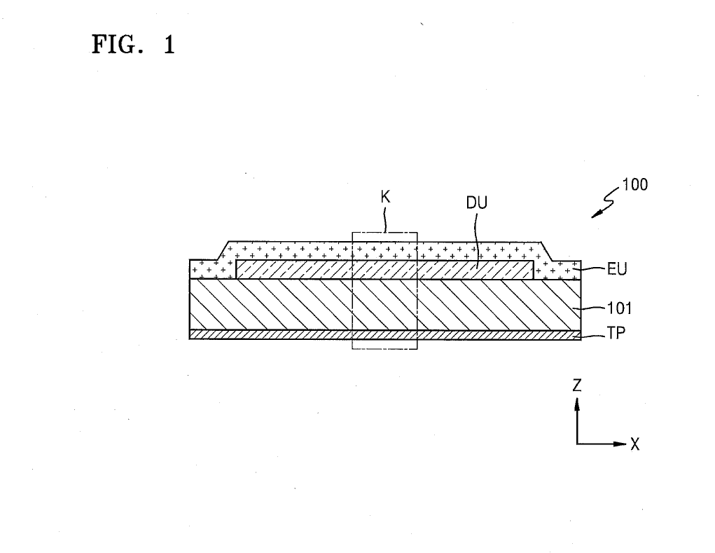

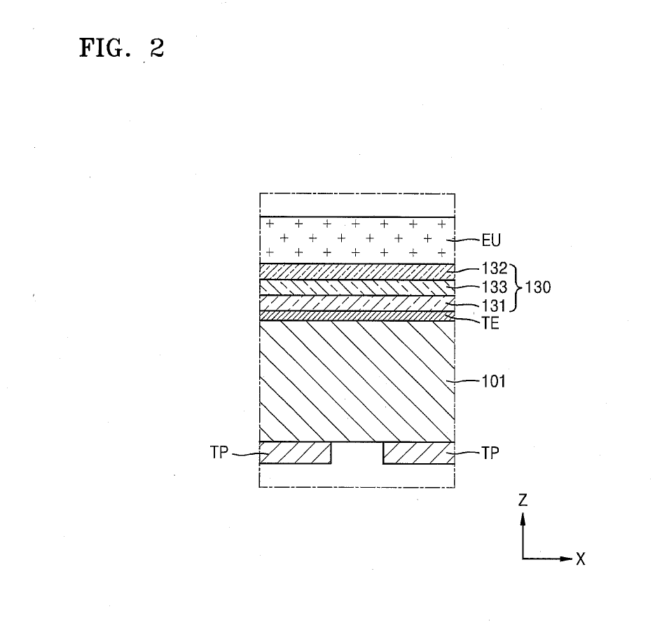

FIG. 1 illustrates a cross-sectional view of a display device 100 according to an exemplary embodiment. FIG. 2 illustrates an enlarged view of a portion K of the display device 100 shown in FIG. 1.

Referring to FIGS. 1 and 2, the display device 100 includes a substrate 101, a display unit (or display layer) DU, a touch pattern TP, and an encapsulating unit (or encapsulating layer) EU.

Elements of the display device 100 are described below in detail.

The substrate 101 can be formed of various materials. For example, the substrate 101 is formed of a glass material.

In some embodiments, the substrate 101 is formed of material having excellent light transmittance. Thus, a visible ray generated in the display unit DU to be described later can pass through the substrate 101 and reach a user. That is, the display device 100 can be of a bottom emission type and the user can recognize an image realized in the display device 100 below the substrate 101 shown in FIG. 1.

In the present embodiment, the substrate 101 is formed of a flexible material, and in some embodiments, the substrate 101 is formed of an organic material. For example, the substrate 101 is formed of an organic material such as polyimide, polyethylene napthalate, polyethyleneterephthalate (PET), polyarylate, polycarbonate, polyether imide (PEI), or polyethersulfone that has excellent heat-resistance and durability.

Although not illustrated, at least one barrier layer (not shown) and at least one buffer layer (not shown) can be selectively formed between the substrate 101 and the display unit DU, and by doing so, it is possible to decrease or to prevent foreign substances, moisture, or outside air from penetrating into the display device 100 via the substrate 101.

The display unit DU is formed on the substrate 101. The display unit DU includes a display device that generates a visible ray for realizing an image that is recognizable to the user.

The display device can be variously formed to generate the visible ray, and for example, is a liquid crystal display device, an organic light-emitting diode (OLED), or the like.

In this disclosure, for convenience of description, it is assumed that the display device includes an OLED 130 as shown in FIG. 2.

In some embodiments, the display device 100 further includes a touch mutual electrode TE.

The display device 100 can sense a user's touch via the touch mutual electrode TE and the touch pattern TP, e.g., when the user touches the touch pattern TP, the display device 100 senses the touch via the touch mutual electrode TE and the touch pattern TP. For example, the display device 100 recognizes the user's touch by detecting a change in capacitance between the touch mutual electrode TE and the touch pattern TP.

In some embodiments, a position of the touch mutual electrode TE is changed, and for example, the touch mutual electrode TE is formed on the OLED 130.

In some embodiments, only the touch pattern TP is formed, and the touch mutual electrode TE is not formed. That is, the display device 100 can recognize a user's touch via only the touch pattern TP. For example, the touch pattern TP has a touch pattern in a first direction and another touch pattern that is electrically insulated from the touch pattern and is arranged in a second direction that crosses the first direction, and the display device 100 can recognize the user's touch by detecting a change in capacitance between the touch pattern in the first direction and the other touch pattern in the second direction.

The OLED 130 can include a first electrode 131, a second electrode 132, and an intermediate layer 133.

The first electrode 131 can be formed on the touch mutual electrode TE by using various conductive materials. In some embodiments, the first electrode 131 is formed of ITO, IZO, ZnO, or In₂O₃. In some embodiments, the first electrode 131 includes a reflective layer formed of Ag, Mg, Al, Pt, Pd, Au, Ni, Nd, Ir, Cr, Li, Yb, or Ca.

The intermediate layer 133 is formed on the first electrode 131. The intermediate layer 133 includes an organic emission layer so as to generate a visible ray. The intermediate layer 133 can be a small-molecule organic layer or a polymer organic layer. Also, the intermediate layer 133 can include the organic emission layer, and can further include at least one of a hole injection layer (HIL), a hole transport layer (HTL), an electron transport layer (ETL), and an electron injection layer (EIL).

The second electrode 132 can be formed on the intermediate layer 133 by using various conductive materials. In some embodiments, the second electrode 132 is formed of a metal including Ag, Mg, Al, Pt, Pd, Au, Ni, Nd, Ir, Cr, Li, or Ca.

The touch pattern TP can be formed on a surface of the substrate 101 opposite the other surface of the substrate 101 that faces the display unit DU. By doing so, the touch pattern TP can affect forming of the display unit DU in a very small degree. The touch pattern TP can have various shapes. For example, the touch pattern TP has a plurality of conductive patterns that extend in one direction, and in this case, the touch mutual electrode TE has a plurality of conductive patterns that extend in one direction that crosses the direction in which the touch pattern TP extends.

Also, as described above, if the touch mutual electrode TE is not used, the display device 100 can recognize a user's touch via only the touch pattern TP, and in this case, the touch pattern TP can include conductive patterns that are insulated from each other and are formed in a first direction and a second direction that crosses the first direction.

The touch pattern TP can be formed of various materials. In some embodiments, the touch pattern TP is formed of a transmissive conductive material, e.g., ITO, IZO, ZnO, AZO, or In₂O₃.

By doing so, when a visible ray that is generated in the display unit DU passes through the substrate 101 and reaches the user, light-shielding due to the touch pattern TP can be sharply decreased. Therefore, the bottom emission type display device 100 can be easily embodied.

The encapsulating unit EU can be formed on the display unit DU and can cover the display unit DU. The encapsulating unit EU can have various shapes, be formed of various materials, and decrease or prevent foreign substances, moisture, or outside air from penetrating into the display unit DU. The encapsulating unit EU can include an organic layer or an inorganic layer. Alternatively, the encapsulating unit EU can be a stack layer of at least one organic layer and at least one inorganic layer.

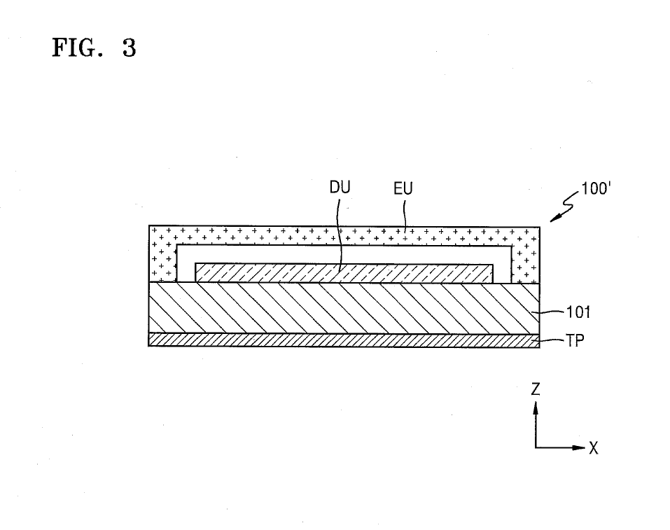

The encapsulating unit EU can have a layer shape as shown in FIG. 1 or can have a cover shape as shown in FIG. 3, where a display device 100′ is illustrated as a modified embodiment of the display device 100.

Although not illustrated, in some embodiments, the encapsulating unit EU is an encapsulation substrate (not shown) that faces the substrate 101, and the encapsulation substrate and the substrate 101 can be bonded to each other by using a sealing member (not shown).

Although not illustrated, a protective layer (not shown) can be further formed on the touch pattern TP by using an insulating material.

In the display device 100 according to the present embodiment, the encapsulating unit EU is formed on one surface of the substrate 101, and the touch pattern TP is formed on the other surface of the substrate 101. By doing so, the touch pattern TP can be easily formed without affecting a characteristic of the display unit DU during forming thereof.

For example, the touch pattern TP is formed on a bottom surface of the substrate 101, i.e., the touch pattern TP is formed on the other surface of the substrate 101 where the display unit DU is not formed, thus, when the touch pattern TP is formed, a degree of freedom with respect to a touch pattern forming process is increased.

Also, since the touch pattern TP is formed on the bottom surface of the substrate 101 and formed of the transmissive conductive material, the bottom emission type display device 100 where an image is realized toward the substrate 101 can be easily embodied.

Also, since the display device 100 does not require a separate panel or a substrate so as to realize a touch recognition function, the thickness of the display device 100 having the touch recognition function can be decreased, and a characteristic of a manufacturing procedure with respect to the display device 100 can be improved.

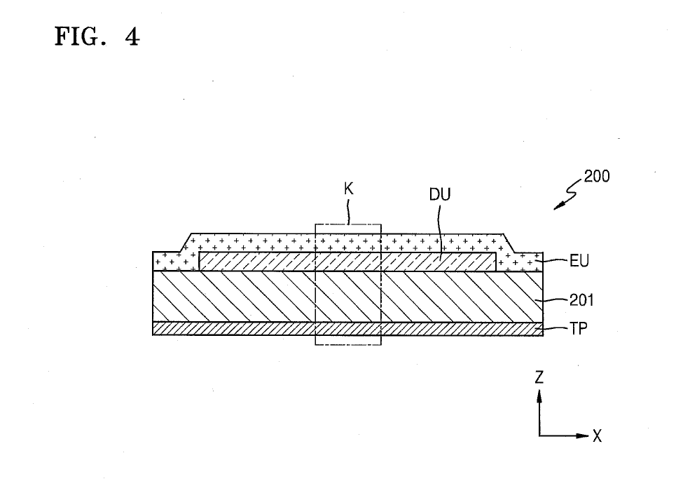

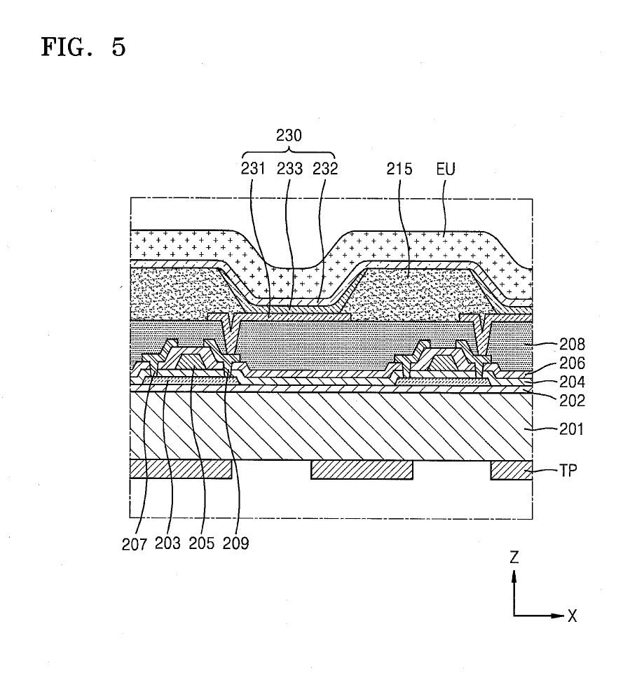

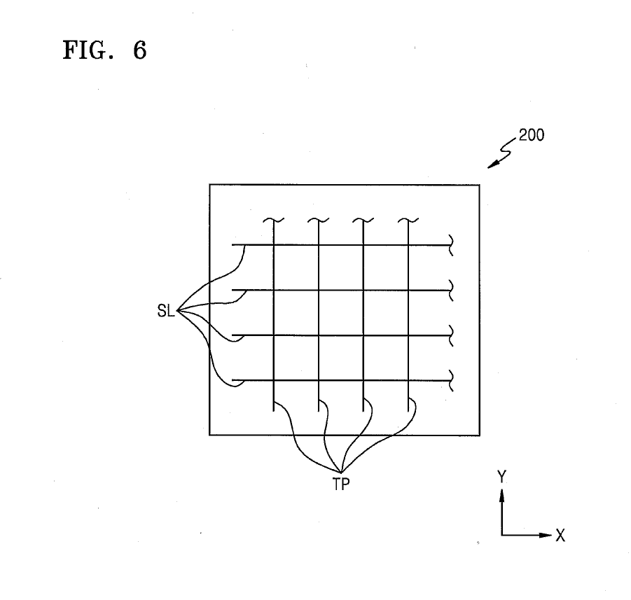

FIG. 4 is a cross-sectional view that illustrates a display device 200 according to another exemplary embodiment. FIG. 5 is a magnified view that illustrates a portion K of the display device 200 shown in FIG. 4. FIG. 6 shows a circuit diagram that illustrates a touch pattern TP of the display device 200 shown in FIG. 4.

Referring to FIGS. 4 through 6, the display device 200 includes a substrate 201, a display unit DU, the touch pattern TP, and an encapsulating unit EU. For convenience of description, the present embodiment will now be described with reference to its characteristics that are different from the previous embodiment.

The display unit DU is formed on the substrate 201, and a display device and a thin film transistor (TFT) are formed in the display unit DU. The display device includes an OLED 230, and the TFT includes an active layer 203, a gate electrode 205, a source electrode 207, and a drain electrode 209.

A material of the substrate 201 is the same as a material of the substrate 101, and thus, detailed descriptions thereof are omitted here.

A buffer layer 202 is formed on the substrate 201. The buffer layer 202 can provide a planar surface on a top surface of the substrate 201, and can decrease or prevent foreign substances, moisture, or outside air from penetrating into the display device 200 via the substrate 201.

The active layer 203 having a predetermined pattern is formed on a top surface of the buffer layer 202. The active layer 203 can be formed of inorganic semiconductor material such as silicon, an organic semiconductor material, or an oxide semiconductor material, and can be formed by selectively injecting a p-type dopant or an n-type dopant.

A gate insulating layer 204 is formed on the active layer 203. The gate electrode 205 is formed on the gate insulating layer 204 so as to have an area that overlaps with the active layer 203.

The display device 200 can include scan lines SL that apply scan signals to the display unit DU. The scan lines SL can be formed of the same material as the gate electrode 205 and can be connected to the gate electrode 205. In some embodiments, the display device 200 includes TFTs that are not shown in FIGS. 4 and 5, and the scan lines SL are formed of the same material as that of the gate electrodes of the TFTs and are connected to the gate electrodes of the TFTs.

An interlayer insulating layer 206 is formed to cover the gate electrode 205, and the source electrode 207 and the drain electrode 209 are formed on the interlayer insulating layer 206.

The source electrode 207 and the drain electrode 209 contact predetermined areas of the active layer 203.

A passivation layer 208 can be formed to cover the source electrode 207 and the drain electrode 209, and a separate planarization layer (not shown) can be further formed on the passivation layer 208.

The OLED 230 is formed on the passivation layer 208. The OLED 230 includes a first electrode 231, an intermediate layer 233, and a second electrode 232.

The first electrode 231 is formed to be electrically connected to one of the source electrode 207 and the drain electrode 209.

A pixel defining layer 215 is formed on the first electrode 231. The pixel defining layer 215 does not cover a predetermined area of a top surface of the first electrode 231. The intermediate layer 233 including an organic emission layer is formed on the top surface of the first electrode 231. The second electrode 232 is formed on the intermediate layer 233.

The touch pattern TP is formed on a bottom surface of the substrate 201, e.g., the touch pattern TP is formed on a surface of the substrate 201 opposite the other surface of the substrate 201 that faces the display unit DU. By doing so, the touch pattern TP can affect forming of the display unit DU in a very small degree. The touch pattern TP can have various shapes. For example, the touch pattern TP includes a plurality of conductive patterns that extend in one direction.

As illustrated in FIG. 6, the touch pattern TP includes a plurality of conductive patterns that extend in one direction that crosses a direction in which the scan lines SL extend. That is, when a user touches the display device 200, the display device 200 can realize a touch recognition function by detecting a change in capacitance between the touch pattern TP and the scan lines SL.

In some embodiments, the display device 200 recognizes a user's touch via only the touch pattern TP, and in this case, the touch pattern TP has conductive patterns that are insulated from each other and are arrayed in a first direction and a second direction that crosses the first direction.

The touch pattern TP can be formed of various materials. In some embodiments, the touch pattern TP is formed of a transmissive conductive material, e.g., ITO, IZO, ZnO, AZO, or In₂O₃.

By doing so, when a visible ray that is generated in the display unit DU passes through the substrate 201 and reaches the user, light-shielding due to the touch pattern TP can be sharply decreased. Therefore, the bottom emission type display device 200 can be easily embodied.

The encapsulating unit EU can be formed on the display unit DU and can cover the display unit DU. The encapsulating unit EU can have various shapes, can be formed of various materials, and can decrease or prevent foreign substances, moisture, or outside air from penetrating into the display unit DU. The encapsulating unit EU can include an organic layer or an inorganic layer. Alternatively, the encapsulating unit EU can be a stack layer of at least one organic layer and at least one inorganic layer.

The encapsulating unit EU can have a cover shape as shown in FIG. 3.

Although not illustrated, in some embodiments, the encapsulating unit EU is an encapsulation substrate (not shown) that faces the substrate 201, and the encapsulation substrate and the substrate 201 are bonded to each other by using a sealing member (not shown).

Although not illustrated, a protective layer (not shown) can be further formed on the touch pattern TP by using an insulating material.

In the display device 200 according to the present embodiment, the encapsulating unit EU is formed on one surface of the substrate 201, and the touch pattern TP is formed on the other surface of the substrate 201. By doing so, the touch pattern TP can be easily formed without affecting a characteristic of the display unit DU during forming thereof.

For example, the touch pattern TP is formed on a bottom surface of the substrate 201, i.e., the touch pattern TP is formed on the other surface of the substrate 201 where the display unit DU is not formed. Thus, when the touch pattern TP is formed, a degree of freedom of a process of forming a touch pattern is increased.

Also, since the touch pattern TP is formed on the bottom surface of the substrate 201 and includes the transmissive conductive material, the bottom emission type display device 200 where an image is realized toward the substrate 201 can be easily embodied.

Also, the touch pattern TP can be formed to cross the scan lines SL that are connected to the gate electrode 205 of the TFT in the display unit DU, so that a touch function can be easily implemented by using the scan lines SL as a touch mutual electrode, without separately forming the touch mutual electrode.

Also, since the display device 200 does not require a separate panel or a substrate so as to realize a touch recognition function, the thickness of the display device 200 having the touch recognition function can be decreased, and a characteristic of a manufacturing procedure with respect to the display device 200 can be improved.

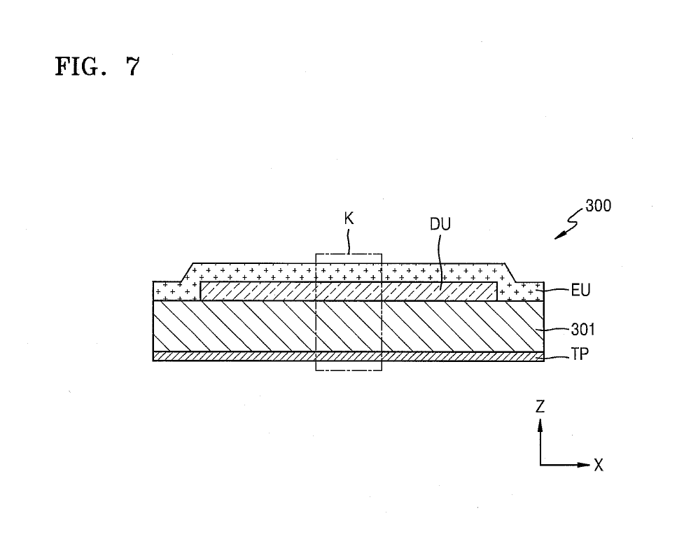

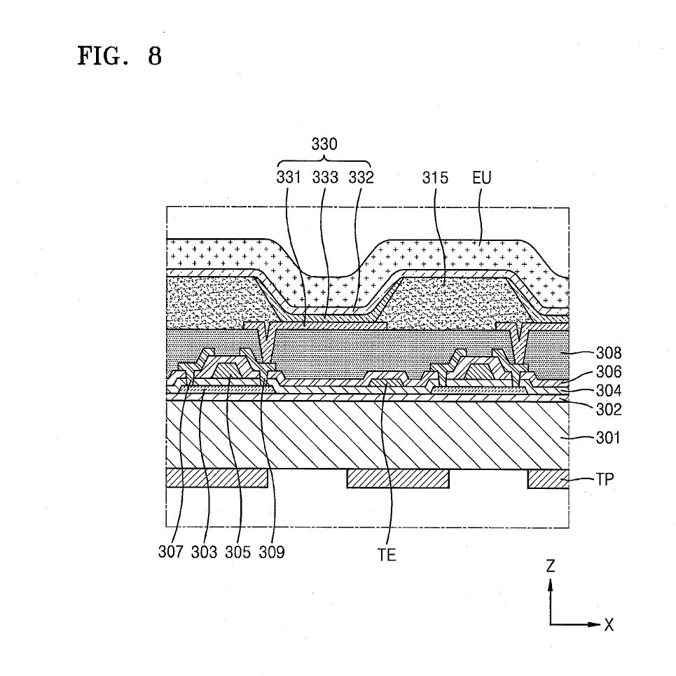

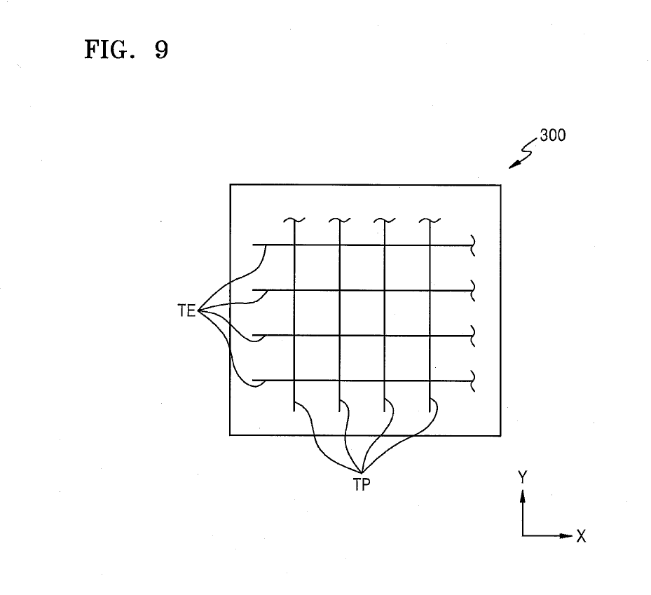

FIG. 7 is a cross-sectional view that illustrates a display device 300 according to another exemplary embodiment. FIG. 8 is a magnified view that illustrates a portion K of the display device 300 shown in FIG. 7. FIG. 9 is a circuit diagram that illustrates a touch pattern TP of the display device 300 shown in FIG. 7.

Referring to FIGS. 7 through 9, the display device 300 includes a substrate 301, a display unit DU, the touch pattern TP, and an encapsulating unit EU. For convenience of description, the present embodiment will now be described with reference to its characteristics that are different from the previous embodiment.

The display unit DU is formed on the substrate 301, and a display device and a thin film transistor (TFT) are formed in the display unit DU. The display device includes an OLED 330, and the TFT includes an active layer 303, a gate electrode 305, a source electrode 307, and a drain electrode 309.

A material of the substrate 301 is the same as a material of the substrate 101, and thus, detailed descriptions thereof are omitted here.

A buffer layer 302 is formed on the substrate 301. The buffer layer 302 can provide a planar surface on a top surface of the substrate 301, and can decrease or prevent foreign substances, moisture, or outside air from penetrating into the display device 300 via the substrate 301.

The active layer 303 having a predetermined pattern is formed on a top surface of the buffer layer 302. The active layer 303 can be formed of an inorganic semiconductor material such as silicon, an organic semiconductor material, or an oxide semiconductor material, and can be formed by selectively injecting a p-type dopant or an n-type dopant.

A gate insulating layer 304 is formed on the active layer 303. The gate electrode 305 is formed on the gate insulating layer 304 so as to have an area that overlaps with the active layer 303.

The display device 300 can include scan lines SL that apply scan signals to the display unit DU. The scan lines SL can be formed of the same material as the gate electrode 305 and can be connected to the gate electrode 305. In some embodiments, the display device 300 includes TFTs that are not shown in FIGS. 7 and 8, and the scan lines SL can be formed of the same material as gate electrodes of the TFTs and can be connected to the gate electrodes of the TFTs.

A touch mutual electrode TE is formed on the gate insulating layer 304.

The display device 300 can sense a user's touch via the touch mutual electrode TE and the touch pattern TP, e.g., when the user touches the touch pattern TP, the display device 300 can sense the touch via the touch mutual electrode TE and the touch pattern TP. For example, the display device 300 recognizes the user's touch by detecting a change in capacitance between the touch mutual electrode TE and the touch pattern TP. The touch mutual electrode TE can be formed of the same material as the gate electrode 305.

In some embodiments, a position of the touch mutual electrode TE is changed. For example, the touch mutual electrode TE is formed on the buffer layer 302. As another example, another insulating layer (not shown) can be further formed between the gate insulating layer 304 and the gate electrode 305, and the touch mutual electrode TE can be formed between the other insulating layer and the gate insulating layer 304.

In some embodiments, the touch mutual electrode TE is formed on an interlayer insulating layer 306 by using a same material as the source electrode 307 or the drain electrode 309.

Referring to FIG. 8, the interlayer insulating layer 306 is formed to cover the gate electrode 305 and the touch mutual electrode TE, and the source electrode 307 and the drain electrode 309 are formed on the interlayer insulating layer 306.

The source electrode 307 and the drain electrode 309 contact predetermined areas of the active layer 303.

A passivation layer 308 can be formed to cover the source electrode 307 and the drain electrode 309, and a separate planarization layer (not shown) can be further formed on the passivation layer 308.

The OLED 330 is formed on the passivation layer 308. The OLED 330 includes a first electrode 331, an intermediate layer 333, and a second electrode 332.

The first electrode 331 is formed to be electrically connected to one of the source electrode 307 and the drain electrode 309.

A pixel defining layer 315 is formed on the first electrode 331. The pixel defining layer 315 does not cover a predetermined area of a top surface of the first electrode 331. The intermediate layer 333 including an organic emission layer is formed on the top surface of the first electrode 331. The second electrode 332 is formed on the intermediate layer 333.

The touch pattern TP is formed on a bottom surface of the substrate 301, e.g., the touch pattern TP is formed on a surface of the substrate 301 opposite the other surface of the substrate 301 that faces the display unit DU. By doing so, the touch pattern TP can affect forming of the display unit DU in a very small degree. The touch pattern TP can have various shapes. For example, the touch pattern TP can include a plurality of conductive patterns that extend in one direction.

As illustrated in FIG. 9, the touch pattern TP includes a plurality of conductive patterns that extend in one direction that crosses a direction in which the touch mutual electrode TE extends. That is, when a user touches the display device 300, the display device 300 can realize a touch recognition function by detecting a change in capacitance between the touch pattern TP and the touch mutual electrode TE.

The touch pattern TP can be formed of various materials. In some embodiments, the touch pattern TP is formed of a transmissive conductive material, e.g., ITO, IZO, ZnO, AZO, or In₂O₃.

By doing so, when a visible ray that is generated in the display unit DU passes through the substrate 301 and reaches the user, light-shielding due to the touch pattern TP can be sharply decreased. Therefore, the bottom emission type display device 300 can be easily embodied.

The encapsulating unit EU can be formed on the display unit DU and can cover the display unit DU. The encapsulating unit EU can have various shapes, can be formed of various materials, and can decrease or prevent foreign substances, moisture, or outside air from penetrating into the display unit DU. The encapsulating unit EU can include an organic layer or an inorganic layer. Alternatively, the encapsulating unit EU can be a stack layer of at least one organic layer and at least one inorganic layer.

The encapsulating unit EU can have a cover shape as shown in FIG. 3.

Although not illustrated, in some embodiments, the encapsulating unit EU is an encapsulation substrate (not shown) that faces the substrate 301, and the encapsulation substrate and the substrate 301 can be bonded to each other by using a sealing member (not shown).

Although not illustrated, a protective layer (not shown) can be further formed on the touch pattern TP by using an insulating material.

In the display device 300 according to the present embodiment, the encapsulating unit EU is formed on one surface of the substrate 301, and the touch pattern TP is formed on the other surface of the substrate 301. Thus, the touch pattern TP can be easily formed without affecting a characteristic of the display unit DU during forming thereof.

For example, the touch pattern TP is formed on a bottom surface of the substrate 301, i.e., the touch pattern TP is formed on the other surface of the substrate 301 where the display unit DU is not formed, thus, when the touch pattern TP is formed, a degree of freedom with respect to a touch pattern forming process is increased.

Also, since the touch pattern TP is formed on the bottom surface of the substrate 301 and is formed of the transmissive conductive material, the bottom emission type display device 300 where an image is realized toward the substrate 301 can be easily embodied.

When the touch mutual electrode TE is formed of the same material as the gate electrode 305 arranged in the display unit DU, production efficiency can be improved. Also, since the touch mutual electrode TE is formed on one of the layers included in the TFT of the display unit DU, the production efficiency can be further improved.

Also, since the display device 300 does not require a separate panel or a substrate so as to realize a touch recognition function, the thickness of the display device 300 having the touch recognition function can be decreased, and a characteristic of a manufacturing procedure with respect to the display device 200 can be improved.

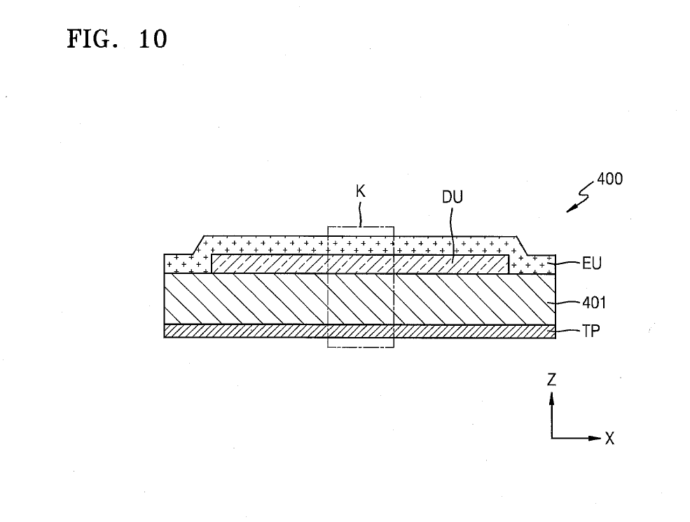

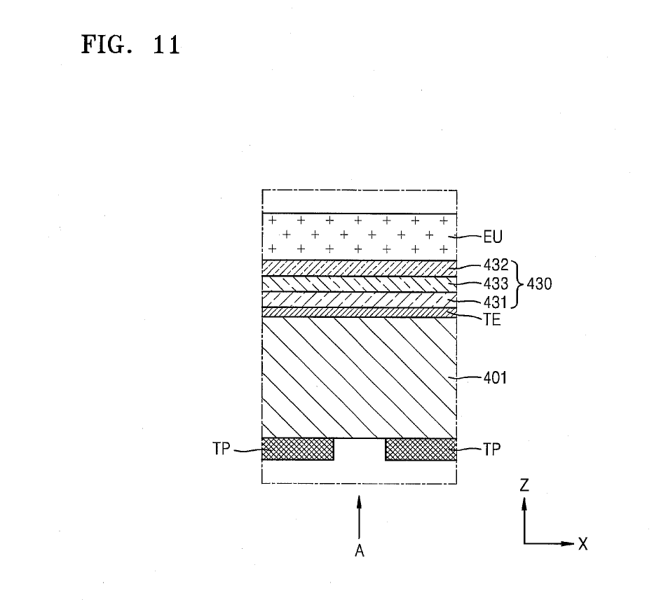

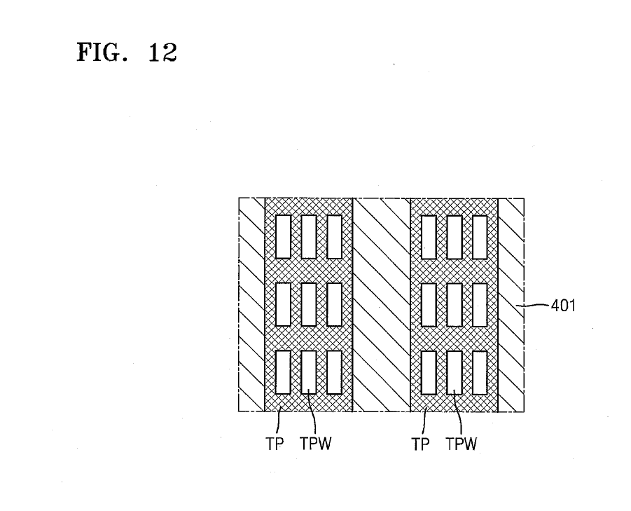

FIG. 10 illustrates a cross-sectional view of a display device 400 according to another exemplary embodiment. FIG. 11 is an enlarged view of a portion K of the display device 400 shown in FIG. 10. FIG. 12 is a plan view of the portion K of FIG. 10 seen in direction A of FIG. 11. For convenience of description, the present embodiment will now be described with reference to characteristics different from the previous embodiment.

Referring to FIGS. 10 through 12, the display device 400 includes a substrate 401, a display unit DU, the touch pattern TP, and an encapsulating unit EU.

The display unit DU is formed on the substrate 401, and the touch pattern TP is formed on a bottom surface of the substrate 401, i.e., a surface of the substrate 401 opposite the other surface of the substrate 401 whereon the display unit DU is formed.

A material of the substrate 401 is the same as the material of the substrate 101, and thus, detailed descriptions thereof are omitted here.

Although not illustrated, at least one barrier layer (not shown) and at least one buffer layer (not shown) can be formed between the substrate 401 and the display unit DU, and by doing so, it is possible to decrease or to prevent foreign substances, moisture, or outside air from penetrating into the display device 400 via the substrate 401.

The display unit DU is formed on the substrate 401. The display unit DU includes an OLED 430 that is a display device.

In some embodiments, the display device 400 further includes a touch mutual electrode TE.

The display device 400 can sense a user's touch via the touch mutual electrode TE and the touch pattern TP, e.g., when the user touches the touch pattern TP, the display device 400 can sense the touch via the touch mutual electrode TE and the touch pattern TP. For example, the display device 400 recognizes the user's touch by detecting a change in capacitance between the touch mutual electrode TE and the touch pattern TP.

In some embodiments, a position of the touch mutual electrode TE changes. For example, the touch mutual electrode TE is formed on the OLED 430.

In some embodiments, only the touch pattern TP is arranged, and the touch mutual electrode TE can be omitted. That is, the display device 400 can recognize the user's touch via only the touch pattern TP. For example, the touch pattern TP includes a touch pattern in a first direction and another touch pattern that is electrically insulated from the touch pattern and is arranged in a second direction that crosses the first direction, and the display device 400 can recognize the user's touch by detecting a change in capacitance between the touch pattern in the first direction and the other touch pattern in the second direction.

The OLED 430 includes a first electrode 431, a second electrode 432, and an intermediate layer 433.

The first electrode 431 can be formed on the touch mutual electrode TE.

The intermediate layer 433 is formed on the first electrode 431. The intermediate layer 433 includes an organic emission layer so as to generate a visible ray.

The second electrode 432 is formed on the intermediate layer 433. The second electrode 432 can be formed of various conductive materials.

The touch pattern TP can be formed on a surface of the substrate 401 opposite the other surface of the substrate 401 that faces the display unit DU. By doing so, the touch pattern TP can affect forming of the display unit DU in a very small degree. The touch pattern TP can have various shapes. For example, the touch pattern TP has a plurality of conductive patterns that extend in one direction, and in this case, the touch mutual electrode TE has a plurality of conductive patterns that extend in one direction that crosses the direction in which the touch pattern TP extends.

Also, as described above, if the touch mutual electrode TE is not arranged, the display device 100 can recognize a user's touch via only the touch pattern TP, and in this case, the touch pattern TP can include conductive patterns that are insulated from each other and are arrayed in a first direction and a second direction that crosses the first direction.

The touch pattern TP can be formed of various materials. In some embodiments, the touch pattern TP is formed of a conductive material and a light-shielding material. For example, the touch pattern TP is formed of chromium (Cr), nickel (Ni), molybdenum (Mo), or iron (Fe).

By doing so, when a visible ray generated in the display unit DU passes through the substrate 401 and reaches a user, reflection of external light can be decreased due to the touch pattern TP, so that a contrast can be improved.

In order to significantly decrease shielding of a visible ray generated in the OLED 430 by the touch pattern TP, the touch pattern TP can have a plurality of openings TPW as illustrated in FIG. 12. The light-shielding by the touch pattern TP can be significantly decreased due to the openings TPW. By doing so, the bottom emission type display device 400 can be easily embodied. The openings TPW can be selectively applied to the previous embodiments.

The encapsulating unit EU can be formed on the display unit DU and can cover the display unit DU. The encapsulating unit EU can have various shapes, can be formed of various materials, and can decrease or prevent foreign substances, moisture, or outside air from penetrating into the display unit DU. The encapsulating unit EU can include an organic layer or an inorganic layer. Alternatively, the encapsulating unit EU can be a stack layer of at least one organic layer and at least one inorganic layer.

The encapsulating unit EU can have a layer shape as shown in FIG. 10 or can have a cover shape as shown in FIG. 3.

Although not illustrated, in some embodiments, the encapsulating unit EU is an encapsulation substrate (not shown) that faces the substrate 401, and the encapsulation substrate and the substrate 401 are bonded to each other by using a sealing member (not shown).

Although not illustrated, a protective layer (not shown) can be further formed on the touch pattern TP by using an insulating material.

In the display device 400 according to the present embodiment, the encapsulating unit EU is formed on one surface of the substrate 401, and the touch pattern TP is formed on the other surface of the substrate 401. By doing so, the touch pattern TP can be easily formed without affecting a characteristic of the display unit DU during forming thereof.

For example, the touch pattern TP is formed on a bottom surface of the substrate 401, i.e., the touch pattern TP is formed on the other surface of the substrate 401 where the display unit DU is not formed, thus, when the touch pattern TP is formed, a degree of freedom with respect to a touch pattern forming process is increased.

Also, since the touch pattern TP is formed on the bottom surface of the substrate 401 and includes the transmissive conductive material, the bottom emission type display device 400 where an image is realized toward the substrate 401 can be easily embodied.

For example, when the touch pattern TP includes the light-shielding material and thus has a black-matrix function, a contrast of the display device 400 can be improved, and here, since the touch pattern TP has the openings TPW, a decrease of a luminescent efficiency can be sharply decreased.

Also, since the display device 400 does not require a separate panel or a substrate so as to realize a touch recognition function, the thickness of the display device 400 having the touch recognition function can be decreased, and a characteristic of a manufacturing procedure with respect to the display device 400 can be improved.

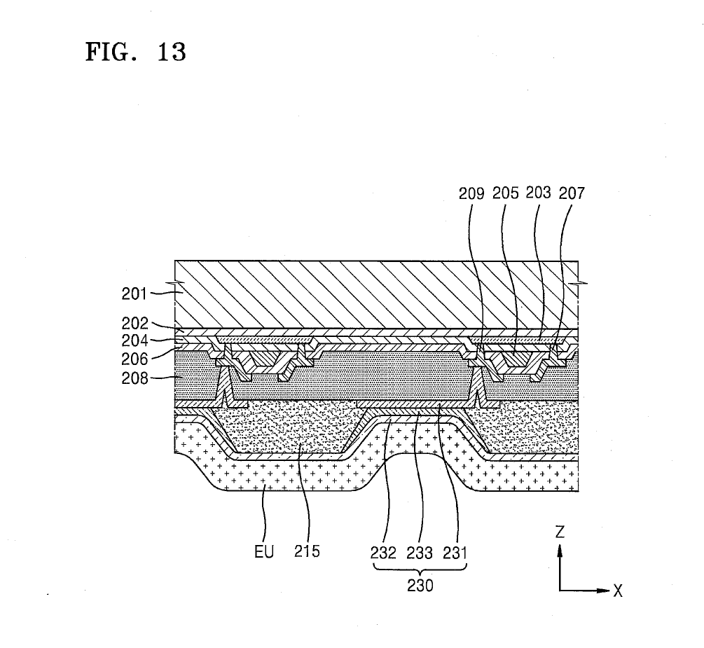

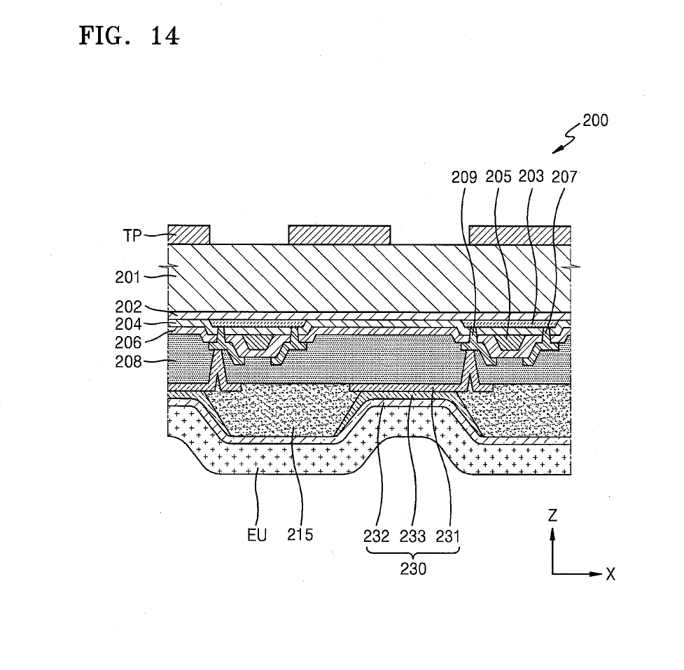

FIGS. 13 and 14 are diagrams illustrating a method of manufacturing a display device, according to an exemplary embodiment.

For convenience of description, in the present embodiment, it is assumed that the display device is the display device 200 of FIG. 2. Although not illustrated, the display devices of the previous embodiments other than the display device 200 of FIG. 2 can also be applied to the method of the present embodiment.

Referring to FIG. 13, a structure excluding the touch pattern TP is formed. That is, the substrate 201, the display unit DU, and the encapsulating unit EU are formed, so that the structure including the substrate 201, the display unit DU, and the encapsulating unit EU is arranged.

Afterward, referring to FIG. 14, the touch pattern TP is formed on a surface of the substrate 201 that is opposite to the other surface of the substrate 201 on which the display unit DU is formed, so that the display device 200 is finally completed.

Referring to FIGS. 13 and 14, the substrate 201, the display unit DU, and the encapsulating unit EU are formed. Then, the structure is flipped over, i.e., the surface of the substrate 201 opposite the other surface of the substrate 201 on which the display unit DU is formed faces upward, and then, a process of forming the touch pattern TP is performed.

However, the described technology is not limited thereto, thus, the structure including the substrate 201, the display unit DU, and the encapsulating unit EU is formed and then the process of forming the touch pattern TP can be performed while the surface of the substrate 201 opposite the other surface of the substrate 201 on which the display unit DU is formed faces downward.

According to the method of manufacturing the display device of the present embodiment, after the display unit DU and the encapsulating unit EU are formed on the substrate 201, the touch pattern TP is formed on the surface of the substrate 201 that is opposite to the other surface of the substrate 201 on which the display unit DU and the encapsulating unit EU are formed. By doing so, when the display unit DU and the encapsulating unit EU are formed, defect occurrence due to the process of forming the touch pattern TP can be fundamentally prevented, and when the touch pattern TP is formed, the process of forming the touch pattern TP can be performed on the surface of the substrate 201, without consideration of the display unit DU and the encapsulating unit EU, so that an efficiency of the process of forming the touch pattern TP can be increased.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

While the inventive technology has been described with reference to the figures, it will be understood by those of ordinary skill in the art that various changes in form and details can be made therein without departing from the spirit and scope as defined by the following claims.

What is claimed is:

1. A display device comprising:
a substrate having first and second surfaces opposing each other;
a display layer formed over the first surface of the substrate and comprising a display element configured to generate an image; and
a touch pattern formed over the second surface of the substrate, wherein the touch pattern is conductive and configured to recognize a touch thereon.

2. The display device of claim 1, further comprising a touch mutual electrode formed over the display layer or in the display layer so as to face the touch pattern.

3. The display device of claim 2, wherein the touch pattern comprises a plurality of first conductive patterns extending in a first direction, and wherein the touch mutual electrode comprises a plurality of second conductive patterns extending in a second direction crossing the first direction.

4. The display device of claim 1, wherein the touch pattern is formed of a transmissive conductive material.

5. The display device of claim 1, wherein the display layer comprises at least one thin-film transistor (TFT) electrically connected to the display element, and wherein the at least one TFT comprises an active layer, a gate electrode, a source electrode, and a drain electrode.

6. The display device of claim 5, further comprising a touch mutual electrode formed of the same material as the gate electrode and facing the touch pattern.

7. The display device of claim 5, further comprising a scan line configured to apply a scan signal to the display element and electrically connected to the gate electrode, wherein the scan line faces the touch pattern, and wherein the touch pattern is further configured to detect a change in a capacitance between the scan line and the touch pattern so as to recognize the touch.

8. The display device of claim 7, wherein the scan line comprises one or more conductive lines extending in a first direction, and wherein the touch pattern comprises a plurality of conductive patterns extending in a second direction crossing the first direction.

9. The display device of claim 5, further comprising a touch mutual electrode formed of the same material as the source electrode or the drain electrode, wherein the touch mutual electrode faces the touch pattern.

10. The display device of claim 5, further comprising a touch mutual electrode formed between the active layer and the gate electrode and facing the touch pattern.

11. The display device of claim 1, wherein the touch pattern is formed of a light-shielding material.

12. The display device of claim 1, wherein the touch pattern has a plurality of openings.

13. The display of claim 12, wherein the openings are configured to decrease light-shielding in the touch pattern.

14. The display device of claim 1, further comprising a protective layer at least partially covering the touch pattern.

15. The display device of claim 1, wherein the substrate is formed of a light-transmitting material.

16. The display device of claim 1, further comprising an encapsulating layer covering the display layer.

17. The display device of claim 1, wherein the display element comprises an organic light-emitting diode (OLED) including a first electrode, a second electrode, and an intermediate layer, and wherein the intermediate layer is formed between the first and second electrodes and comprises an organic emission layer.

18. A method of manufacturing a display device, the method comprising:
forming a display layer over a first surface of a substrate, wherein the display layer comprises a display element configured to generate an image; and
forming a touch pattern over a second surface of the substrate opposing the first surface, wherein the touch pattern is conductive and configured to recognize a touch thereon.

19. The method of claim 18, further comprising forming an encapsulating layer covering the display layer,
wherein the touch pattern formed after the encapsulating layer.

20. The method of claim 18, further comprising flipping over the substrate,
wherein the touch pattern is formed after the encapsulating layer, and wherein the substrate is flipped over after the encapsulating layer is formed.
